(19) United States
(12) Patent Application Publication
(10) Pub. No.: US 2026/0082480 A1
(43) Pub. Date: Mar. 19, 2026

(54) COMPOSITE BOARD PACKAGE STRUCTURE

(71) Applicant: TONG HSING ELECTRONIC INDUSTRIES, LTD., Taoyuan City (TW)

(72) Inventors: DEI-CHENG LIU, Taipei City (TW); CHUN-CHIEH LIAO, Taoyuan City (TW); JHIH-WEI LAI, Taoyuan City (TW); JIAN-YU SHIH, Taoyuan City (TW)

(21) Appl. No.: 18/956,311

(22) Filed: Nov. 22, 2024

(30) Foreign Application Priority Data
Sep. 19, 2024 (TW) 113135363

(51) Int. Cl. H05K 1/11; B41J 2/14; H05K 1/03

(52) U.S. Cl. CPC H05K 1/116; B41J 2/1433; H05K 1/0306

(57) ABSTRACT

A composite board package structure includes a first ceramic board, a plurality of conductive pillars embedded in the first ceramic board, a plurality of bonding pads formed on an outer surface of the first ceramic board, a plurality of layout circuits formed on an inner surface of the first ceramic board, a photosensitive photoresist wall formed on the inner surface, a photosensitive photoresist layer connected to the photosensitive photoresist wall, and a second ceramic board that is connected to the photosensitive photoresist layer. Two ends of each of the conductive pillars are respectively connected to one of the bonding pads and one of the layout circuits, and the photosensitive photoresist wall surrounds the layout circuits. The photosensitive photoresist layer, the photosensitive photoresist wall, and the first ceramic board jointly define an enclosed space that receives the layout circuits therein.

### CROSS-REFERENCE TO RELATED PATENT APPLICATION

This application claims the benefit of priority to Taiwan Patent Application No. 113135363, filed on Sep. 19, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a composite board package structure, and more particularly to a composite board package structure with a photosensitive photoresist for adhering boards thereof.

### BACKGROUND OF THE DISCLOSURE

Development of a conventional board structure has gradually been unable to meet increasingly diverse demands on product specifications. Accordingly, how to provide improvements to the conventional board structure has become an issue to be addressed in the relevant field.

### SUMMARY OF THE DISCLOSURE

In response to the above-referenced technical inadequacies, the present disclosure provides a composite board package structure for effectively improving on the issues associated with conventional board structures.

In order to solve the above-mentioned problems, one of the technical aspects adopted by the present disclosure is to provide a composite board package structure, which includes a direct plated copper (DPC) substrate, a plurality of layout circuits, and a ceramic cover. The DPC substrate includes a first ceramic board, a metal wall, a plurality of conductive pillars, and a plurality of connection pads. The first ceramic board has an inner surface and an outer surface that is opposite to the inner surface. The metal wall is ring-shaped and is formed on the inner surface of the first ceramic board in a DPC manner. A part of the first ceramic board arranged inside of the metal wall is defined as a layout segment. The conductive pillars are embedded in the layout segment of the first ceramic board. Each of the conductive pillars has an inner contact exposed from the inner surface and an outer contact that is exposed from the outer surface. The connection pads are formed on the outer surface of the first ceramic board in the DPC manner. The connection pads are respectively connected to the outer contacts of the conductive pillars. The layout circuits are formed on the inner surface of the first ceramic board and are surrounded inside of the metal wall. The layout circuits are respectively connected to the inner contacts of the conductive pillars. The ceramic cover includes a second ceramic board spaced apart from the first ceramic board and a photosensitive photoresist ring that is formed on the second ceramic board. The ceramic cover is bonded onto the DPC substrate through the photosensitive photoresist ring, and the metal wall is embedded in the photosensitive photoresist ring, such that the second ceramic board, the photosensitive photoresist ring, and the first ceramic board jointly define an enclosed space that accommodates the layout circuits therein.

In order to solve the above-mentioned problems, another one of the technical aspects adopted by the present disclosure is to provide a composite board package structure, which includes a first ceramic board, a plurality of conductive pillars, a plurality of connection pads, a plurality of layout circuits, a photosensitive photoresist wall, a photosensitive photoresist layer, and a second ceramic board. The first ceramic board has an inner surface and an outer surface that is opposite to the inner surface. The conductive pillars are embedded in the first ceramic board, and each of the conductive pillars has an inner contact exposed from the inner surface and an outer contact that is exposed from the outer surface. The connection pads are formed on the outer surface of the first ceramic board, and the connection pads are respectively connected to the outer contacts of the conductive pillars. The layout circuits are formed on the inner surface of the first ceramic board and are respectively connected to the inner contacts of the conductive pillars. The photosensitive photoresist wall is ring shaped and is formed on the inner surface of the first ceramic board. The photosensitive photoresist wall surrounds at an outer side of the layout circuits. The photosensitive photoresist layer is bonded onto the photosensitive photoresist wall. The photosensitive photoresist layer, the photosensitive photoresist wall, and the first ceramic board jointly define an enclosed space that accommodates the layout circuits therein. The second ceramic board is bonded to the photosensitive photoresist layer.

In order to solve the above-mentioned problems, yet another one of the technical aspects adopted by the present disclosure is to provide a composite board package structure, which includes a ceramic board, a thin film, a photosensitive photoresist wall, and a layout board. The ceramic board has an inner surface and an outer surface that is opposite to the inner surface. The ceramic board has an input hole penetrating therethrough. The thin film is disposed on the inner surface of the ceramic board and defines a plurality of bubble formation regions. The photosensitive photoresist wall is ring-shaped and is formed on the thin film. The layout board has a plurality of output holes penetrating therethrough. The layout board is bonded to the photosensitive photoresist wall, and the layout board, the photosensitive photoresist wall, the thin film, and the ceramic board jointly define an accommodating space that is in spatial communication with the input hole and the output holes. The output holes respectively correspond in position to the bubble formation regions of the thin film, such that when the accommodating space of the composite board package structure receives liquid passing through the input hole, any one of the bubble formation regions of the thin film is configured to selectively form a bubble that pushes the liquid to extrude a droplet by passing through a corresponding one of the output holes.

Therefore, the composite board package structure provided by the present disclosure is formed in a configuration of heterogeneous integration for having a diverse cooperation of components and improving dimensional accuracy of components thereof, thereby meeting the increasingly diverse product requirements.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a composite board package structure according to a first embodiment of the present disclosure;

FIG. 2 is a schematic cross-sectional view taken along line II-II of FIG. 1;

FIG. 3 is a schematic cross-sectional view taken along line III-III of FIG. 1;

FIG. 4 is a schematic cross-sectional view showing the composite board package structure in another configuration according to the first embodiment of the present disclosure;

FIG. 5 is a schematic perspective view of the composite board package structure according to a second embodiment of the present disclosure;

FIG. 6 is a schematic cross-sectional view taken along line VI-VI of FIG. 5;

FIG. 7 is a schematic cross-sectional view taken along line VII-VII of FIG. 5;

FIG. 8 is a schematic cross-sectional view showing the composite board package structure in another configuration according to the second embodiment of the present disclosure;

FIG. 9 is a schematic perspective view of the composite board package structure according to a third embodiment of the present disclosure;

FIG. 10 is a schematic top view of FIG. 9;

FIG. 11 is a schematic cross-sectional view taken along line XI-XI of FIG. 9; and

FIG. 12 is a schematic cross-sectional view showing an operation of the composite board package structure of FIG. 11.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on. ” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

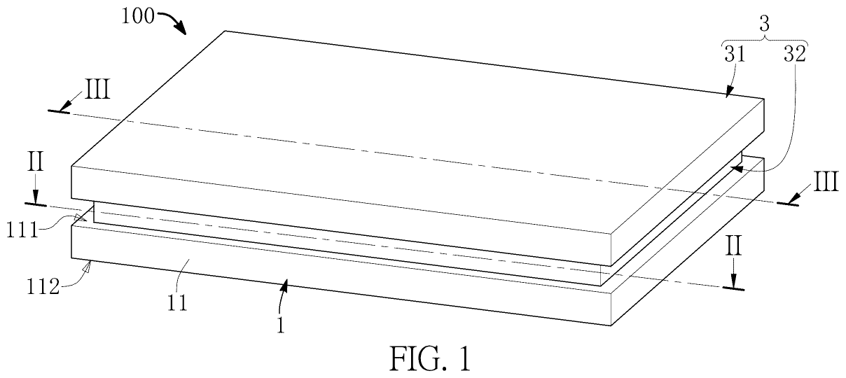

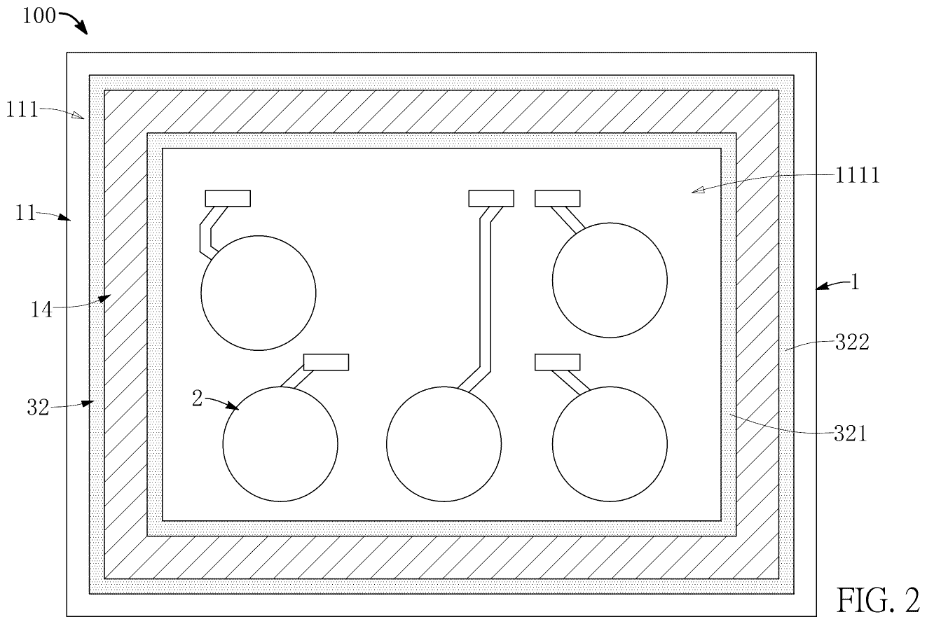

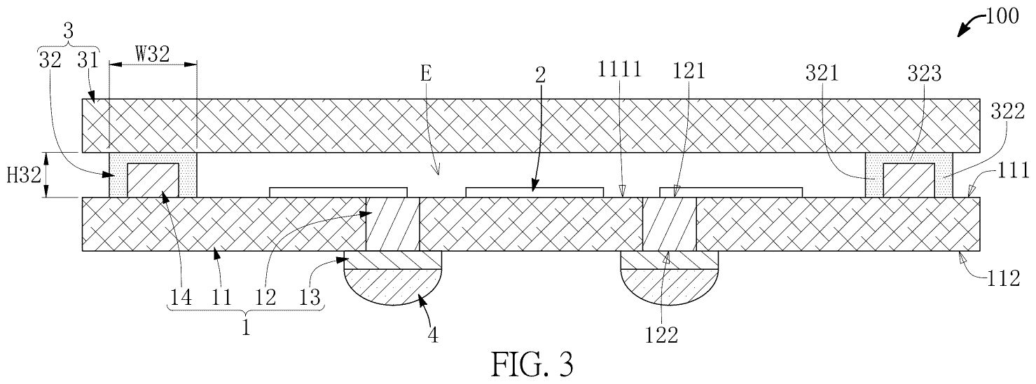

Referring to FIG. 1 to FIG. 4, a first embodiment of the present disclosure is provided. As shown in FIG. 1 to FIG. 3, the present embodiment provides a composite board package structure 100 that can be applied to an adaptive driving beam headlamp (ADB), a COMS image sensor (CIS), or a surface acoustic wave (SAW) filter according to practical requirements, but the present disclosure is not limited thereto.

In the present embodiment, the composite board package structure 100 is formed through a photolithography process and a heterogeneous integration of ceramic metal substrate, and the composite board package structure 100 includes a direct plated copper (DPC) substrate 1, a plurality of layout circuits 2 formed on an inner side of the DPC substrate 1, and a ceramic cover 3 that is bonded onto the DPC substrate 1.

The DPC substrate 1 in the present embodiment includes a first ceramic board 11, a metal wall 14 directly formed on an inner side of the first ceramic board 11, a plurality of conductive pillars 12 embedded in the first ceramic board 11, and a plurality of connection pads 13 that are directly formed on an outer side of the first ceramic board 11.

The first ceramic board 11 has an inner surface 111 and an outer surface 112 that is opposite to the inner surface 111. The metal wall 14 and the connection pads 13 are manufactured by processing two metal layers (not shown in the drawings) that are respectively formed on the inner surface 111 and the outer surface 112 in the DPC manner. For example, the two metal layers are processed through photoresist coating and photolithography technology to respectively form the metal wall 14 having a specific pattern and the connection pads 13.

Specifically, the metal wall 14 is ring-shaped and is formed on the inner surface 111 of the first ceramic board 11 in the DPC manner, and a part of the first ceramic board 11 arranged inside of the metal wall 14 is defined as a layout segment 1111. The conductive pillars 12 are embedded in the layout segment 1111 of the first ceramic board 11, and each of the conductive pillars 12 has an inner contact 121 exposed from the inner surface 111 and an outer contact 122 that is exposed from the outer surface 112. The connection pads 13 are formed on the outer surface 112 in the DPC manner, and the connection pads 13 are respectively connected to the outer contacts 122 of the conductive pillars 12.

The layout circuits 2 are formed on the inner surface 111 of the first ceramic board 11 and are surrounded inside of the metal wall 14. The layout circuits 2 are respectively connected to the inner contacts 121 of the conductive pillars 12. In other words, the layout circuits 2 are located on the layout segment 1111 and are lower than the metal wall 14 with respect to the inner surface 111. The specific shape or configuration of the layout circuits 2 can be changed or adjusted according to practical requirements, and the present disclosure is not limited thereto.

The ceramic cover 3 includes a second ceramic board 31 spaced apart from the first ceramic board 11 and a photosensitive photoresist ring 32 that is formed on the second ceramic board 31. It should be noted that the photosensitive photoresist ring 32 is pre-formed on the second ceramic board 31 through the photolithography technology to have a predetermined shape and size, thereby precisely controlling the accuracy of the photosensitive photoresist ring 32 in the composite board package structure 100.

Specifically, the ceramic cover 3 is bonded onto the DPC substrate 1 through the photosensitive photoresist ring 32, the metal wall 14 is embedded in the photosensitive photoresist ring 32, and an outer lateral side of the second ceramic board 31 can be flush with an outer lateral side of the first ceramic board 11, but the present disclosure is not limited thereto. Accordingly, the second ceramic board 31, the photosensitive photoresist ring 32, and the first ceramic board 11 jointly define an enclosed space E that accommodates the layout circuits 2 therein.

Specifically, the photosensitive photoresist ring 32 in the present embodiment can be an SU-8 photosensitive permanent binder, but the present disclosure is not limited thereto. The photosensitive photoresist ring 32 is located on the inner surface 111 of the first ceramic board 11 and covers the metal wall 14. In other words, the photosensitive photoresist ring 32 is substantially arranged along an outer edge of the layout segment 1111.

In the present embodiment, a height H32 of the photosensitive photoresist ring 32 can be within a range from 25 μm to 1000 μm, and a width W32 of the photosensitive photoresist ring 32 can be within a range from 25 μm to 100 μm. In other words, the photosensitive photoresist ring 32 has an inner segment 321, an outer segment 322 being opposite to the inner segment 321, and a bonding segment 323 that is connected to the inner segment 321 and the outer segment 322.

The inner segment 321 covers an inner side of the metal wall 14, a bottom of the inner segment 321 is disposed on the inner surface 11, and the inner segment 321 of the photosensitive photoresist ring 32 is preferably not in contact with any one of the layout circuits 2. The outer segment 322 covers an outer side of the metal wall 14, a bottom of the outer segment 322 is disposed on the inner surface 11, and the outer segment 322 of the photosensitive photoresist ring 32 is preferably located inside of the outer lateral side of the second ceramic board 31, but the present disclosure is not limited thereto.

Moreover, the bonding segment 323 is connected to a top end of the inner segment 321 and a top end of the outer segment 322, the bonding segment 323 is sandwiched between the second ceramic board 31 and the metal wall 14, and the second ceramic board 31 and the metal wall 14 are adhered and fixed to each other through the bonding segment 323.

In summary, the composite board package structure 100 in the present embodiment is formed in a configuration of heterogeneous integration (e.g., the DPC substrate 1 is connected and fixed to the photosensitive photoresist ring 32 of the ceramic cover 3) for having a diverse cooperation of components and improving dimensional accuracy of components thereof, thereby meeting the increasingly diverse product requirements.

In addition, the composite board package structure 100 can further include a plurality of Au-Sn eutectic solders 4 respectively disposed on the connection pads 13 and configured to be soldered onto an electronic component (not shown in the drawings), but the present disclosure is not limited thereto. For example, in other embodiments of the present disclosure not shown in the drawings, the composite board package structure 100 can be provided without the Au-Sn eutectic solders 4 according to practical requirements.

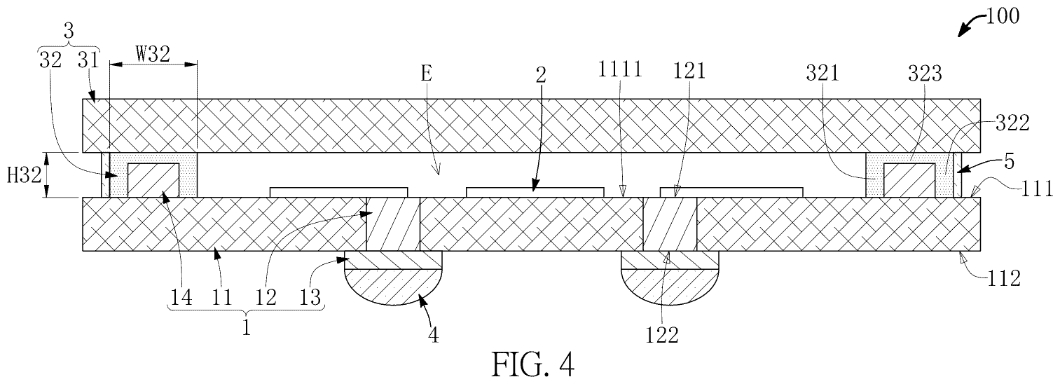

Moreover, as shown in FIG. 4, the composite board package structure 100 can further include a reflective film 5 that is coated on the outer segment 322 of the photosensitive photoresist ring 32 for allowing the composite board package structure 100 to meet a broader range of product requirements.

### Second Embodiment

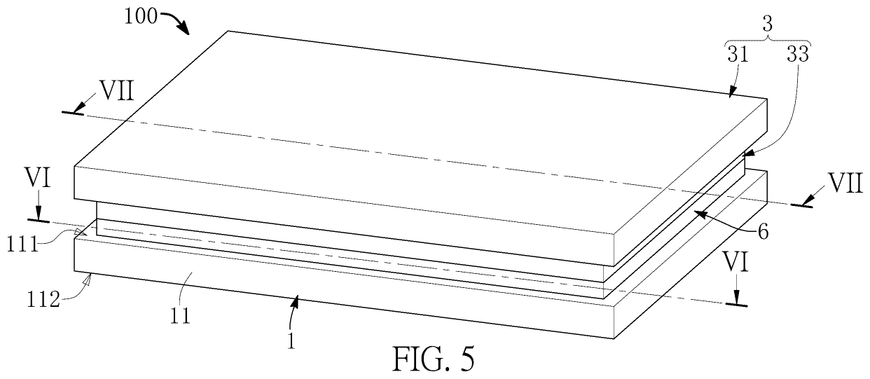

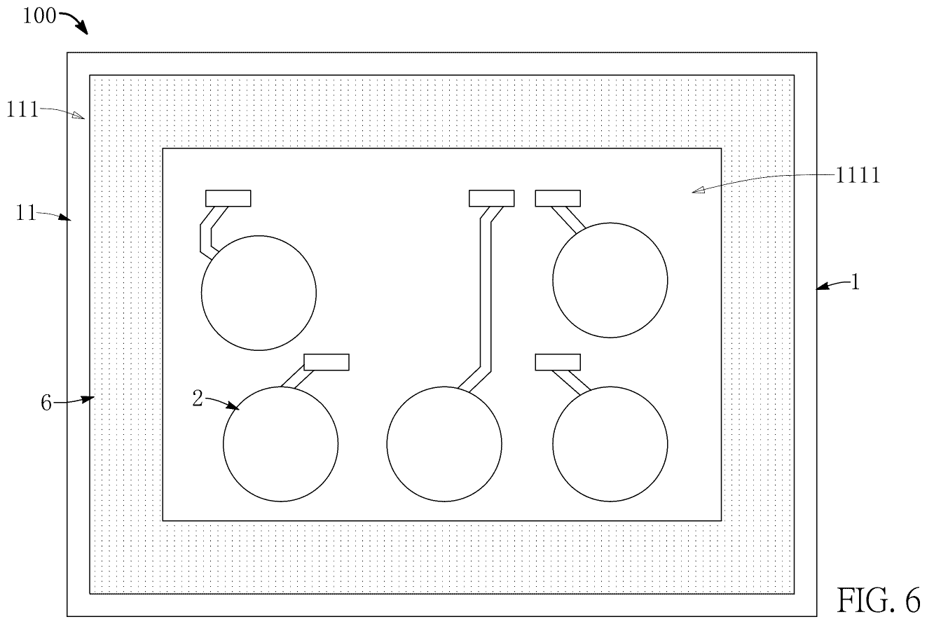

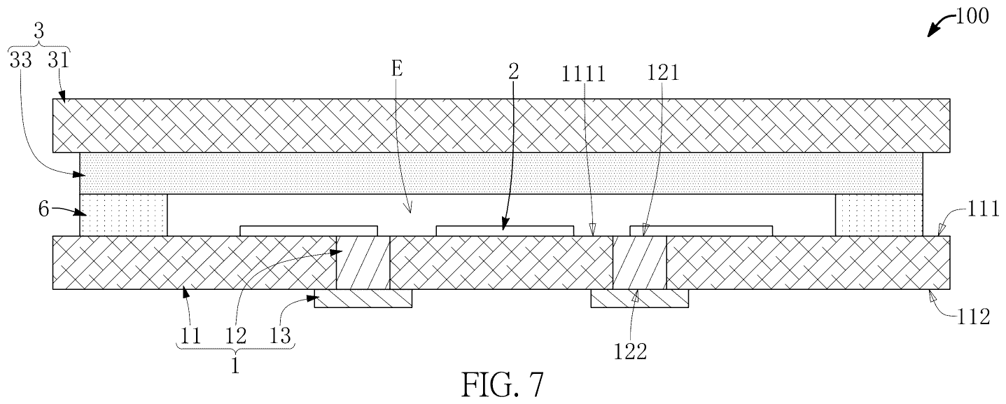

Referring to FIG. 5 to FIG. 8, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

As shown in FIG. 5 to FIG. 7, the present embodiment provides a composite board package structure 100 that can be applied to an ADB, a CIS, or a SAW filter according to practical requirements, but the present disclosure is not limited thereto.

In the present embodiment, the composite board package structure 100 is formed through a photolithography process and a heterogeneous integration of ceramic metal substrate, the composite board package structure 100 includes a first ceramic board 11, a plurality of conductive pillars 12 embedded in the first ceramic board 11, a plurality of connection pads 13 formed on an outer side of the first ceramic board 11, a plurality of layout circuits 2 formed on an inner side of the first ceramic board 11, a photosensitive photoresist wall 6 formed on the first ceramic board 11, a photosensitive photoresist layer 33 stacked on the photosensitive photoresist wall 6, and a second ceramic board 31 that is bonded to the photosensitive photoresist wall 6.

It should be noted that the structures and manufacturing method of the first ceramic board 11, the conductive pillars 12, the connection pads 13, and the layout circuits 2 in the present embodiment are substantially identical to those of the first embodiment, and are not described in the following description for the sake of brevity. Moreover, the first ceramic board 11, the conductive pillars 12, and the connection pads 13 in the present embodiment can be jointly defined as a DPC substrate 1.

The photosensitive photoresist wall 6 is ring shaped and is formed on the inner surface 111 of the first ceramic board 11. The photosensitive photoresist wall 6 surrounds at an outer side of the layout circuits 2. Moreover, a part of the first ceramic board 11 arranged inside of the photosensitive photoresist wall 6 is defined as a layout segment 1111, and the photosensitive photoresist wall 6 is preferably not in contact with any one of the layout circuits 2. In other words, the layout circuits 2 are located on the layout segment 1111 and are lower than the photosensitive photoresist wall 6 with respect to the inner surface 111. The specific shape or configuration of the layout circuits 2 can be changed or adjusted according to practical requirements, and the present disclosure is not limited thereto.

In addition, each of the photosensitive photoresist wall 6 and the photosensitive photoresist layer 33 in the present embodiment can be an SU-8 photosensitive permanent binder, but the present disclosure is not limited thereto. The photosensitive photoresist wall 6 is formed on the inner surface 111 of the first ceramic board 11 through the photolithography technology to have a predetermined shape and size, thereby precisely controlling the accuracy of the photosensitive photoresist wall 6.

Moreover, the photosensitive photoresist layer 33 is bonded onto the photosensitive photoresist wall 6, and the photosensitive photoresist layer 33, the photosensitive photoresist wall 6, and the first ceramic board 11 jointly define an enclosed space E that accommodates the layout circuits 2 therein.

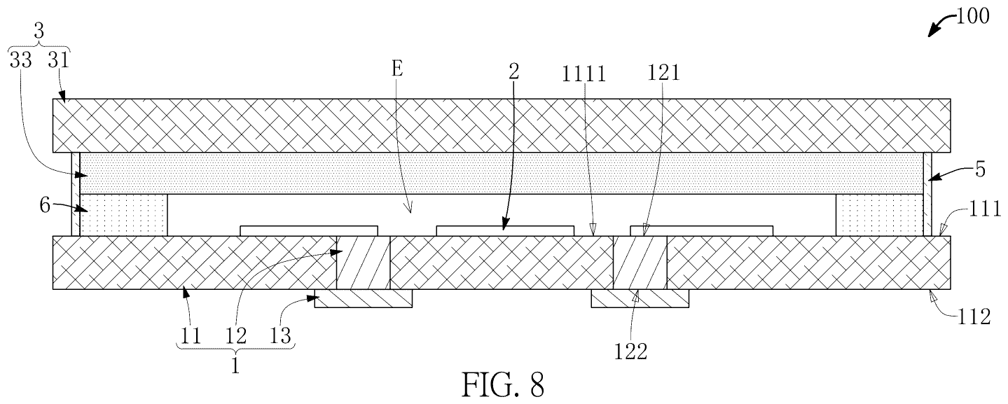

In the present embodiment, an outer lateral side of the photosensitive photoresist layer 33 is preferably flush with an outer lateral side of the photosensitive photoresist wall 6. In addition, as shown in FIG. 8, the composite board package structure 100 can further include a reflective film 5 that is coated on the outer lateral side of the photosensitive photoresist wall 6 and the outer lateral side of the photosensitive photoresist layer 33, thereby allowing the composite board package structure 100 to meet a broader range of product requirements.

It should be noted that the photosensitive photoresist layer 33 is pre-formed on the second ceramic board 31 in the photolithography technology to have a predetermined shape and size, thereby precisely controlling the accuracy of the photosensitive photoresist layer 33. In other words, the photosensitive photoresist layer 33 and the second ceramic board 31 in the present embodiment can be jointly defined as a ceramic cover 3, and the ceramic cover 3 is bonded to the photosensitive photoresist wall 6 through the photosensitive photoresist layer 33. In addition, the photosensitive photoresist wall 6 can be pre-formed on the photosensitive photoresist layer 33 in the photolithography technology (e.g., the ceramic cover 33 further includes the photosensitive photoresist wall 6), but the present disclosure is not limited thereto.

In summary, the composite board package structure 100 in the present embodiment is formed in a configuration of heterogeneous integration (e.g., the first ceramic board 11 and the second ceramic board 31 are bonded and fixed to each other through the photosensitive photoresist wall 6 and the photosensitive photoresist layer 33) for having a diverse cooperation of components and improving dimensional accuracy of components thereof, thereby meeting the increasingly diverse product requirements.

### Third Embodiment

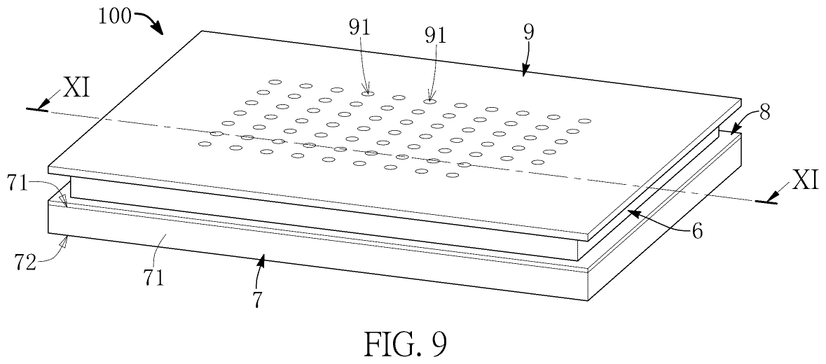

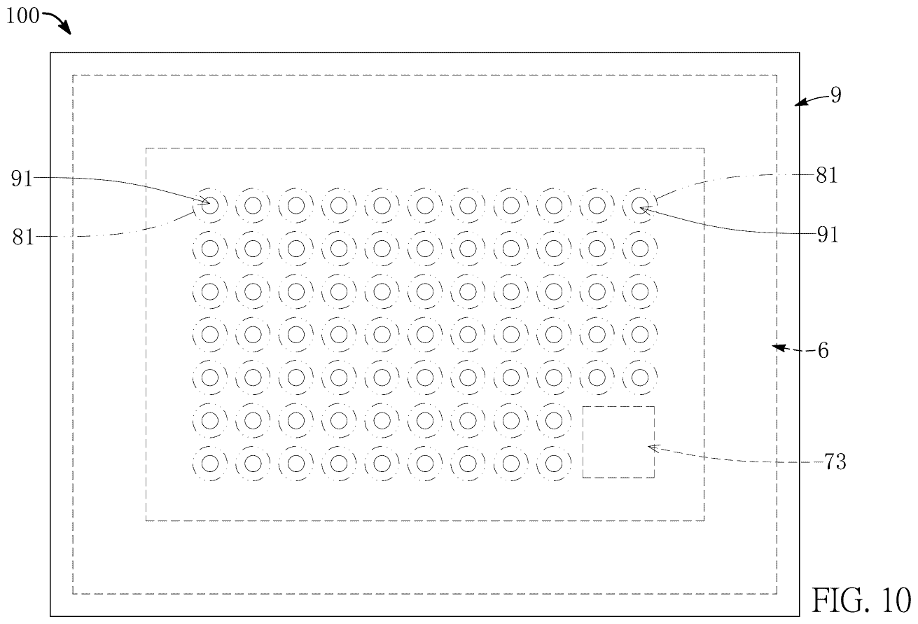

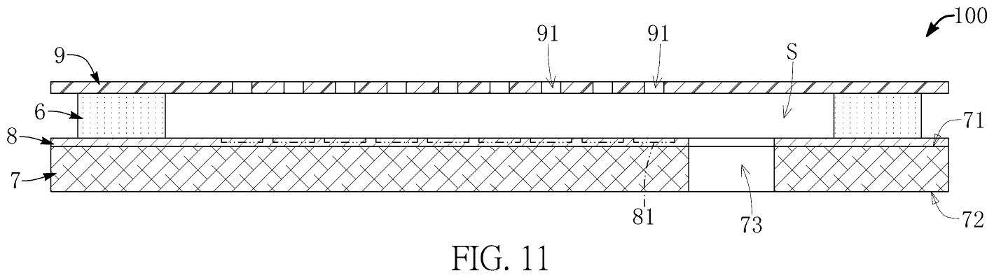

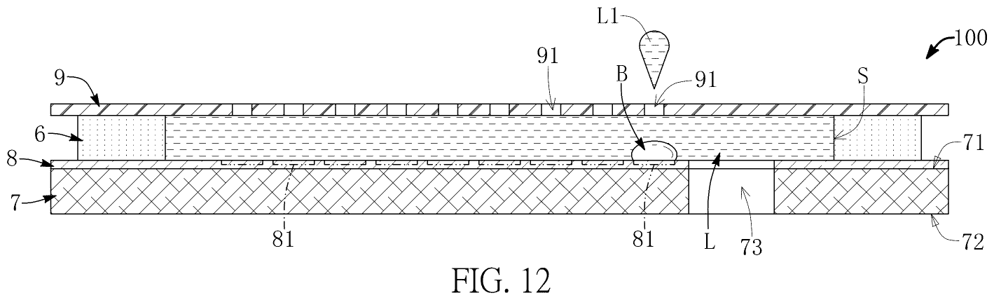

Referring to FIG. 9 to FIG. 12, a third embodiment of the present disclosure, which is similar to the first embodiment of the present disclosure, is provided. For the sake of brevity, descriptions of the same components in the first and third embodiments of the present disclosure will be omitted herein, and the following description only discloses different features between the first and third embodiments.

The present embodiment provides a composite board package structure 100 that can be applied to an ink jet printhead structure according to practical requirements, but the present disclosure is not limited thereto. The composite board package structure 100 includes a ceramic board 7, a thin film 8 arranged on an inner side of the ceramic board 7, a photosensitive photoresist wall 6 formed on the thin film 8, and a layout board 9 that is bonded to the photosensitive photoresist wall 6.

The ceramic board 7 has an inner surface 71 and an outer surface 72 that is opposite to the inner surface 71, and the ceramic board 7 has an input hole 73 penetrating therethrough. Moreover, the thin film 8 is disposed on the inner surface 71 of the ceramic board 7 and defines a plurality of bubble formation regions 81. The bubble formation regions 81 of the thin film 8 are preferably in a matrix arrangement, but the present disclosure is not limited thereto.

The photosensitive photoresist wall 6 is ring-shaped and is formed on the thin film 8, and the photosensitive photoresist wall 6 surrounds at an outer side of the bubble formation regions 81. It should be noted that the photosensitive photoresist wall 6 in the present embodiment can be an SU-8 photosensitive permanent binder, but the present disclosure is not limited thereto.

The layout board 9 is a flexible board and has a plurality of output holes 91 penetrating therethrough. The output holes 91 of the layout board 9 are preferably in a matrix arrangement. Moreover, the layout board 9 is bonded to the photosensitive photoresist wall 6, the output holes 91 respectively correspond in position to the bubble formation regions 81 of the thin film 8 (e.g., each of the output holes 91 is located directly above one of the bubble formation regions 81), and an outer lateral side of the ceramic board 7, an outer lateral side of the thin film 8, an outer lateral side of the photosensitive photoresist wall 6, and an outer lateral side of the layout board 9 are preferably flush with each other, but the present disclosure is not limited thereto.

In the present embodiment, the layout board 9, the photosensitive photoresist wall 6, the thin film 8, and the ceramic board 7 jointly define an accommodating space S that is in spatial communication with the input hole 73 and the output holes 91. Accordingly, when the accommodating space S of the composite board package structure 100 receives liquid L (e.g., ink) passing through the input hole 73, any one of the bubble formation regions 81 of the thin film 8 is configured to selectively form a bubble B that pushes the liquid L to extrude a droplet L1 by passing through a corresponding one of the output holes 91. The composite board package structure 100 in the present embodiment can be configured to form the droplet L1 in a printed electrode manner, but the present disclosure is not limited thereto.

### Beneficial Effects of the Embodiments

In conclusion, the composite board package structure provided by the present disclosure is formed in a configuration of heterogeneous integration for having a diverse cooperation of components and improving dimensional accuracy of components thereof, thereby meeting the increasingly diverse product requirements.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A composite board package structure, comprising:
a direct plated copper (DPC) substrate including:
a first ceramic board having an inner surface and an outer surface that is opposite to the inner surface;
a metal wall being ring-shaped and formed on the inner surface of the first ceramic board in a DPC manner, wherein a part of the first ceramic board arranged inside of the metal wall is defined as a layout segment;
a plurality of conductive pillars embedded in the layout segment of the first ceramic board, wherein each of the conductive pillars has an inner contact exposed from the inner surface and an outer contact that is exposed from the outer surface;
a plurality of connection pads formed on the outer surface of the first ceramic board in the DPC manner, wherein the connection pads are respectively connected to the outer contacts of the conductive pillars;
a plurality of layout circuits formed on the inner surface of the first ceramic board and surrounded inside of the metal wall, wherein the layout circuits are respectively connected to the inner contacts of the conductive pillars; and
a ceramic cover including:
a second ceramic board spaced apart from the first ceramic board; and
a photosensitive photoresist ring formed on the second ceramic board, wherein the ceramic cover is bonded onto the DPC substrate through the photosensitive photoresist ring, and the metal wall is embedded in the photosensitive photoresist ring, such that the second ceramic board, the photosensitive photoresist ring, and the first ceramic board jointly define an enclosed space that accommodates the layout circuits therein.

2. The composite board package structure according to claim 1, wherein the photosensitive photoresist ring includes:
an inner segment covering an inner side of the metal wall;
an outer segment covering an outer side of the metal wall; and
a bonding segment connected to the inner segment and the outer segment, wherein the bonding segment is sandwiched between the second ceramic board and the metal wall, and the second ceramic board and the metal wall are adhered and fixed to each other through the bonding segment.

3. The composite board package structure according to claim 1, wherein the inner segment of the photosensitive photoresist ring is not in contact with any one of the layout circuits.

4. The composite board package structure according to claim 1, further comprising a reflective film that is coated on the outer segment of the photosensitive photoresist ring.

5. The composite board package structure according to claim 1, further comprising a plurality of Au-Sn eutectic solders respectively disposed on the connection pads and configured to be soldered onto an electronic component.

6. The composite board package structure according to claim 1, wherein a height of the photosensitive photoresist ring is within a range from 25 μm to 1000 μm, and a width of the photosensitive photoresist ring is within a range from 25 μm to 100 μm.

7. A composite board package structure, comprising:
a first ceramic board having an inner surface and an outer surface that is opposite to the inner surface;
a plurality of conductive pillars embedded in the first ceramic board, wherein each of the conductive pillars has an inner contact that is exposed from the inner surface and an outer contact that is exposed from the outer surface;
a plurality of connection pads formed on the outer surface of the first ceramic board, wherein the connection pads are respectively connected to the outer contacts of the conductive pillars;
a plurality of layout circuits formed on the inner surface of the first ceramic board and respectively connected to the inner contacts of the conductive pillars;
a photosensitive photoresist wall being ring shaped and formed on the inner surface of the first ceramic board, wherein the photosensitive photoresist wall is surroundingly arranged at an outer side of the layout circuits;
a photosensitive photoresist layer bonded onto the photosensitive photoresist wall, wherein the photosensitive photoresist layer, the photosensitive photoresist wall, and the first ceramic board jointly define an enclosed space that accommodates the layout circuits therein; and
a second ceramic board bonded to the photosensitive photoresist layer.

8. The composite board package structure according to claim 7, wherein an outer lateral side of the photosensitive photoresist wall is flush with an outer lateral side of the photosensitive photoresist layer.

9. The composite board package structure according to claim 8, further comprising a reflective film coated on the outer lateral side of the photosensitive photoresist wall and the outer lateral side of the photosensitive photoresist layer.

10. The composite board package structure according to claim 7, wherein the first ceramic board, the conductive pillars, and the connection pads are jointly defined as a direct plated copper (DPC) substrate, and the photosensitive photoresist layer and the second ceramic board are jointly defined as a ceramic cover.

11. A composite board package structure, comprising:
a ceramic board having an inner surface and an outer surface that is opposite to the inner surface, wherein the ceramic board has an input hole penetrating therethrough;
a thin film disposed on the inner surface of the ceramic board and defining a plurality of bubble formation regions;
a photosensitive photoresist wall being ring-shaped and formed on the thin film; and
a layout board having a plurality of output holes penetrating therethrough, wherein the layout board is bonded to the photosensitive photoresist wall, and the layout board, the photosensitive photoresist wall, the thin film, and the ceramic board jointly define an accommodating space that is in spatial communication with the input hole and the output holes;
wherein the output holes respectively correspond in position to the bubble formation regions of the thin film, such that when the accommodating space of the composite board package structure receives liquid passing through the input hole, any one of the bubble formation regions of the thin film is configured to selectively form a bubble that pushes the liquid to extrude a droplet by passing through a corresponding one of the output holes.

12. The composite board package structure according to claim 11, wherein the output holes are in a matrix arrangement, and the composite board package structure is configured to form the droplet in a printed electrode manner.

13. The composite board package structure according to claim 11, wherein the layout board is a flexible board, and an outer lateral side of the ceramic board, an outer lateral side of the thin film, an outer lateral side of the photosensitive photoresist wall, and an outer lateral side of the layout board are flush with each other.

14. The composite board package structure according to claim 11, wherein the composite board package structure is an ink jet printhead structure.
